(19) United States
(12) Patent Application Publication
(10) Pub. No.: US 2024/0039510 A1
(43) Pub. Date: Feb. 1, 2024

(54) ACOUSTIC WAVE DEVICES WITH RESONANCE-TUNED LAYER STACK AND METHOD OF MANUFACTURE

(71) Applicant: RF360 Europe GMBH, Munich (DE)

(72) Inventors: Maximilian Schiek, Puchheim (DE); Christian Ceranski, München (DE); Thomas Metzger, München (DE); Willi Aigner, Moosinning (DE); Franz Sterr, München (DE)

(21) Appl. No.: 17/814,994

(22) Filed: Jul. 26, 2022

(51) Int. Cl. H03H 9/13; H03H 3/02; H03H 9/17; H03H 9/02

(52) U.S. Cl. CPC H03H 9/13; H03H 3/02; H03H 9/17; H03H 9/0211; H03H 2003/025

(57) ABSTRACT

A bulk acoustic wave (BAW) device with resonance-tuned layer stack is disclosed. The BAW device includes two acoustic resonators with top electrodes in different regions on a top side of a piezoelectric layer. The BAW device includes an acoustic mirror on a bottom side of the piezoelectric layer and a bottom electrode between the acoustic mirror and the piezoelectric layer. The piezoelectric layer includes a recess in a second region on the bottom side of the piezoelectric layer. The bottom electrode is disposed in the recess on the bottom side of the piezoelectric layer. A distance between a first top electrode in a first region and the bottom electrode may be greater than a distance between a second top electrode in the second region and the bottom electrode.

### BACKGROUND

### Field of the Disclosure

The technology of the disclosure relates generally to micro-acoustic devices and, more particularly, to bulk acoustic wave (BAW) solidly mounted resonators (SMR).

### II. BACKGROUND

Wireless devices, such as cellular telephones, communicate by transmitting and receiving electromagnetic waves through the air. Cellular telephones, for example, are wireless devices allowed to operate only in limited ranges of radio frequencies, and those ranges vary depending on the geographical region (e.g., country) of the world. Thus, cellular telephones worldwide need to include filters for blocking certain frequencies while passing others. The frequencies transmitted by a wireless device can be filtered by micro-acoustic devices that are small enough to fit into a handheld device. Examples of micro-acoustic devices include surface acoustic wave (SAW) resonators and bulk acoustic wave (BAW) resonators. SAW and BAW resonators convert electromagnetic waves into acoustic waves and back into electromagnetic waves using inter-digitated electrodes on top of a piezoelectric material or layers of piezoelectric material sandwiched between electrodes, respectively. Battery-powered handheld wireless devices have strict energy efficiency requirements, causing manufacturers of micro-acoustic devices to strive for highly efficient operation. In this regard, the quality of the piezoelectric material and the containment of the acoustic energy created in the piezoelectric material, as well as mode suppression in the (BAW) resonator, are of significant concern. Improvements are sought in these aspects of micro-acoustic device manufacturing.

### SUMMARY

Aspects disclosed in the detailed description include bulk acoustic wave (BAW) devices with resonance-tuned layer stack. A method of manufacturing acoustic wave devices is also disclosed. A BAW filter device includes at least two acoustic resonators that have different resonance frequencies due to having different piezoelectric layer thicknesses between their electrodes. An exemplary BAW device with two acoustic resonators includes top electrodes on different regions of a first surface on a first side of a piezoelectric layer. The BAW device includes an acoustic mirror on a second side of the piezoelectric layer and a bottom electrode between the acoustic mirror and the piezoelectric layer. A recess in the second side in the second region of the piezoelectric layer provides a different second thickness of the piezoelectric layer in the second region than a first thickness in a first region of the piezoelectric layer. In some examples, the distance between the first top electrode and the bottom electrode in the first region is greater than a distance between the second top electrode and the bottom electrode in the second region.

In this regard, in one aspect, a BAW device is disclosed. The BAW device comprises a piezoelectric layer. The BAW device comprises a first top electrode on a top side of the piezoelectric layer in a first region of the piezoelectric layer and a second top electrode on the top side of the piezoelectric layer in a second region of the piezoelectric layer. The BAW device further comprises an acoustic mirror on a bottom side of the piezoelectric layer and a bottom electrode between the acoustic mirror and the piezoelectric layer. The piezoelectric layer comprises a recess on the bottom side in the second region of the piezoelectric layer.

In another aspect, a method of fabricating a BAW device is disclosed. The method comprises forming a piezoelectric layer on a first substrate and forming a recess in a second region of the piezoelectric layer. The method includes forming a bottom electrode on the piezoelectric layer. The method further includes forming an acoustic mirror comprising a first material on the bottom electrode. The method includes planarizing the first material to form a bonding surface. The method includes bonding a second substrate to the bonding surface. The method includes removing the first substrate. The method further includes forming a first top electrode in a first region of the piezoelectric layer and forming a second top electrode in the second region of the piezoelectric layer.

### BRIEF DESCRIPTION OF THE DRAWINGS

FIG. 1 is an illustration of a cross-sectional view of an exemplary acoustic wave (AW) device, including top electrodes above a top side of a piezoelectric layer and a bottom electrode disposed in a first region of a bottom side of the piezoelectric layer and in a recess in a second region of the bottom side of the piezoelectric layer;

FIG. 2 is an illustration of a cross-sectional view of a conventional BAW device in which a top electrode is disposed in a recess on a top surface of a piezoelectric layer;

FIG. 3 is a flowchart illustrating an exemplary method for fabricating a BAW device, as illustrated in FIG. 1;

FIGS. 4A-4H are illustrations of cross-sectional views of stages of fabrication of the exemplary BAW device in FIG. 1, with top electrodes above a first side and a bottom electrode disposed in first and second regions on a second side of a piezoelectric layer;

FIGS. 5A-5H are a flowchart describing the stages of fabrication of the exemplary BAW device shown in FIGS. 4A-4H;

FIG. 6 is an illustration of a cross-sectional view of another exemplary acoustic device, including a top electrode and an interdigitated transducer (IDT) on a top side of a piezoelectric layer and a bottom electrode disposed in a first region and in a recess in a second region of the piezoelectric layer;

FIG. 7 is an illustration of a cross-sectional view of another exemplary acoustic device, including a bottom electrode disposed in a recess in a region of a piezoelectric layer;

FIG. 8 is a block diagram of an exemplary wireless communications device that can include the BAW device of FIG. 1; and

FIG. 9 is a block diagram of an exemplary processor-based system that can include the BAW device of FIG. 1.

### DETAILED DESCRIPTION

With reference now to the drawing figures, several exemplary aspects of the present disclosure are described. The word “exemplary” is used herein to mean “serving as an example, instance, or illustration.” Any aspect described herein as “exemplary” is not necessarily to be construed as preferred or advantageous over other aspects.

Aspects disclosed in the detailed description include bulk acoustic wave (BAW) devices with resonance tuned layer stack. A method of manufacturing acoustic wave devices is also disclosed. A BAW filter device includes at least two acoustic resonators that have different resonance frequencies due to having different piezoelectric layer thicknesses between their electrodes. An exemplary BAW device with two acoustic resonators includes top electrodes on different regions of a first surface on a first side of a piezoelectric layer. The BAW device includes an acoustic mirror on a second side of the piezoelectric layer and a bottom electrode between the acoustic mirror and the piezoelectric layer. A recess on the second side in the second region of the piezoelectric layer creates a different first thickness of the piezoelectric layer in a first region of a first top electrode than a second thickness of the piezoelectric layer in a second region. In some examples, the distance between the first top electrode and the bottom electrode in the first region is greater than a distance between the second top electrode and the bottom electrode in the second region.

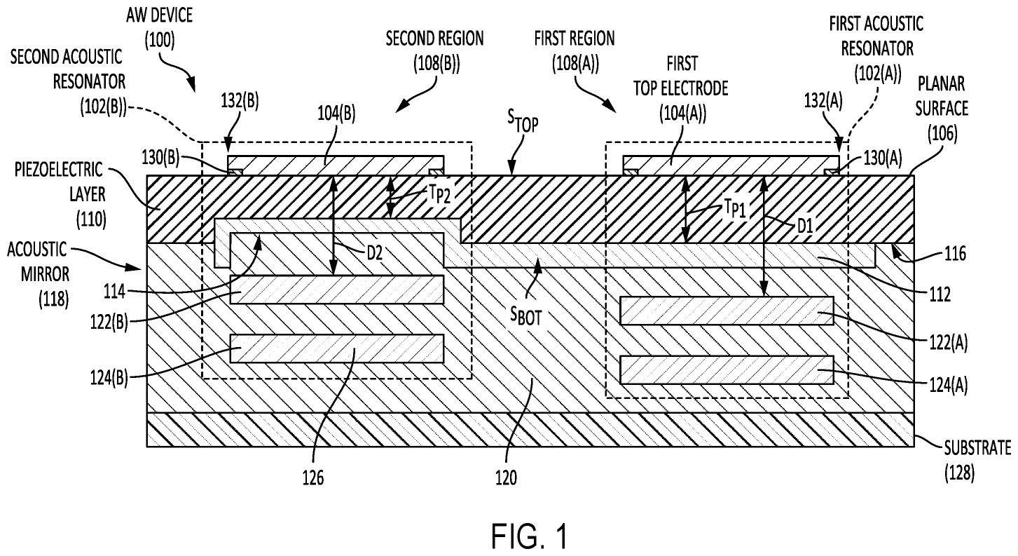

In this regard, FIG. 1 is an illustration of a cross-sectional view of an exemplary BAW device 100, including a first acoustic resonator 102A and a second acoustic resonator 102B. The first acoustic resonator 102A and the second acoustic resonator 102B may resonate at different frequencies to filter acoustic waves in one or more frequency ranges. The first acoustic resonator and the second acoustic resonator (and, if present, any further acoustic resonators of the BAW device) may be provided on a common structure, such as on or over a common substrate 128. The BAW device 100 may be referred to as a bulk acoustic wave (BAW) resonator, a BAW solidly mounted resonator (SMR), or a thin-film bulk acoustic resonator (FBAR or TFBAR). In BAW resonators, the resonant frequencies may depend on a thickness of a piezoelectric layer (e.g., for a single, homogeneous piezoelectric layer). In particular, the thickness of the piezoelectric layer may determine a fraction of a wavelength of a resonant acoustic wave, which corresponds to a frequency of an electromagnetic wave provided as a voltage at the electrodes of the piezoelectric layer. The first acoustic resonator 102A includes a first top electrode 104A on or above an, optionally planar, surface 106 in a first region 108A of a piezoelectric layer 110. The second acoustic resonator 102B includes a second top electrode 104B that is also on or above the, optionally planar, surface 106 but is disposed in a second region 108B of the piezoelectric layer 110. The first acoustic resonator 102A and the second acoustic resonator 102B are on or above a first side or top side STOP of the piezoelectric layer 110. It should be understood that the terms “top” and “bottom” are descriptive of the example having the orientation in FIG. 1 and are not intended to be limiting in this regard. In some examples, the terms “top” and “bottom” are relative terms with respect to the common substrate 128 on or above which the first and second acoustic resonators 102A, 102B are provided as layer stacks.

The BAW device 100 also includes a bottom electrode 112 on a second side S_{BOT} of the piezoelectric layer 110. The bottom electrode 112 may be shared by the first and second acoustic resonators 102A and 102B. The piezoelectric layer 110 has a first thickness T_{P1} that determines a first distance between the first top electrode 104A and the bottom electrode 112 in the first region 108A. The piezoelectric layer 110 has a second thickness T_{P2} that determines a distance between the second top electrode 104B and the bottom electrode 112 in the second region 108B. A varying voltage between the first top electrode 104A and the bottom electrode 112 causes expansion and contraction of the piezoelectric layer 110 at a resonant frequency F1 based on the first thickness T_{P1}. The first thickness T_{P1} of the piezoelectric layer 110 from the bottom electrode 112 disposed in the recess 114 to the top side STOP of the piezoelectric layer 110 is less than the second thickness T_{P2} of the piezoelectric layer 110 from the bottom electrode 112 disposed in the first region 108(A) to the top side STOP of the piezoelectric layer 110.

A resonant frequency of the second acoustic resonator 102B may be higher than that of the first acoustic resonator 102A due to the second thickness T_{P2} being smaller than the first thickness T_{P1}, causing the acoustic waves therein to have a shorter (resonant) wavelength. In the illustrative example of FIG. 1, the first thickness T_{P1} is greater than the second thickness T_{P2} because the piezoelectric layer 110 has been thinned to form recess 114 on the bottom side S_{BOT} in the second region 108B. In some examples, additional thinning of the piezoelectric layer 110 in the first region 108A or the second region 108B may be achieved on the top side STOP.

The bottom electrode 112 disposed in the second region 108B on the second side S_{BOT} of the piezoelectric layer 110 is disposed in the recess 114. In the first region 108A on the second side S_{BOT} of the piezoelectric layer 110, the bottom electrode 112 is disposed (directly) underneath (i.e., against) a surface 116. In some examples, the piezoelectric layer 110 may also have a recess (not shown) in the first region 108 A on the second side S_{BOT} in which the bottom electrode 112 would be disposed. Adjusting the second thickness T_{P2} of the piezoelectric layer 110 in the second region 108B by thinning the second side S_{BOT} to a particular thickness is employed to “tune” the second acoustic resonator 102B to a particular resonant frequency. Tuning the first acoustic resonator 102A to the first thickness T_{P1} in the first region 108A may be achieved by growing the piezoelectric layer 110 to the first thickness T_{P1} or by thinning the piezoelectric layer 110 from a greater thickness to the first thickness T_{P1}.

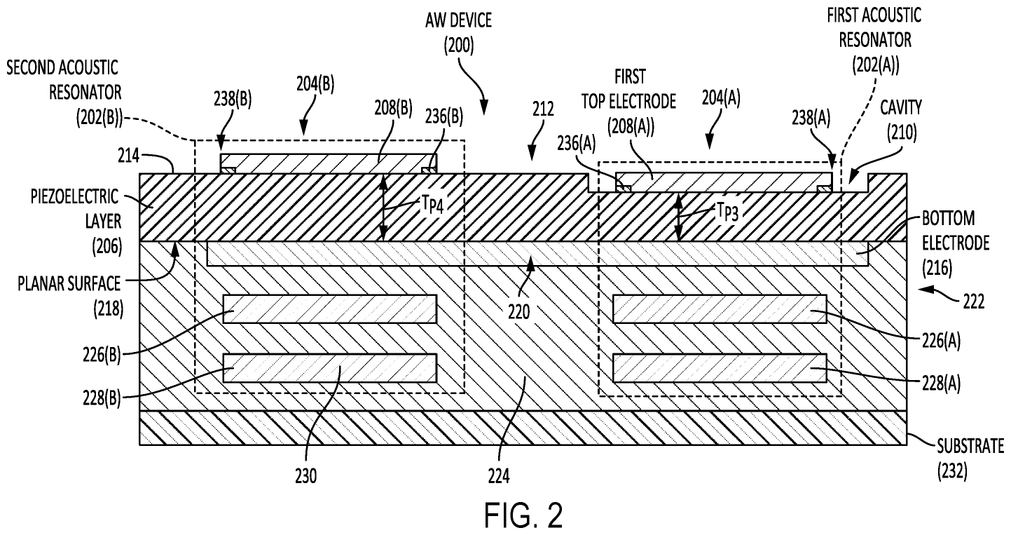

The present disclosure is, however, not limited to achieving different thicknesses of the piezoelectric layer 110 in the first region 108A and the second region 108B through thinning on the second side S_{BOT}. Different thicknesses of the piezoelectric layer 110 in the first region 108A and the second region 108B may alternatively or additionally be achieved through thinning on the first side STOP. As described below with respect to FIG. 2, thinning on the first side STOP may lead to lateral acoustic features 130A and 130B being at different focal distances from a lens of a photolithographic apparatus. Consequently, one or more steps for forming the lateral acoustic feature 130A may be repeated to form the lateral acoustic feature 130B, which may raise manufacturing costs. In some aspects, thinning is applied only on the second side S_{BOT} of the piezoelectric layer 110. In other words, a top surface 106 of the piezoelectric layer 110 may be planar. In these aspects, lateral acoustic features 130A and 130B may be formed in a single photolithographic process.

The piezoelectric layer 110 may be aluminum nitride (AlN) or aluminum scandium nitride (AlScN), for example. The first and second top electrodes 104A and 104B, and the bottom electrode 112 may be molybdenum (Mo), tungsten (W), alloys of copper (Cu) or aluminum (Al), or layers of any of Mo, W, Cu, and/or Al.

A measure of the efficiency of the BAW device 100 (e.g., quality factor Q) as a component in an integrated circuit, for example, is negatively impacted by losses of the acoustic wave energy applied as a voltage. For this reason, the BAW device 100 also includes, on a side of the bottom electrode 112 opposite to the piezoelectric layer 110, an acoustic mirror 118, such as a Bragg mirror, to help reduce loss of acoustic energy (e.g., to reflect acoustic waves back to the piezoelectric layer 110). The acoustic mirror 118 may include a first material 120 having a first acoustic impedance (e.g., amorphous silicon dioxide, SiO₂). The first material 120 may be disposed against (e.g., directly against) the bottom electrode 112 and the underside of the piezoelectric layer 110. The acoustic mirror 118 may further include layers 122A, 122B, 124A, and 124B of a second material 126 with a second acoustic impedance (e.g., tungsten). Layer 122A is opposite to the first top electrode 104A in the first region 108A, and layer 122B is opposite to the second top electrode 104B in the second region 108B. The first material 120 is disposed between the bottom electrode 112 and each of layers 122A and 122B of the second material 126. Layer 122A is at a distance D1 from the optionally planar surface 106 in the first region 108A, and layer 122B is at a second distance D2 from the optionally planar surface 106 in the second region 108B, where D1 may be greater than D2. The first layer 122A of the second material 126 is disposed on the first material 120 at a first distance D1 from the top side STOP of the piezoelectric layer 110 in the first region 108(A) and the second layer 122B of the second material 126 is disposed on the first material 120 at a second distance D2 from the top side STOP of the piezoelectric layer 110 in the second region 108(B). In other words, the first distance D1 from the first layer 122A of the second material 126 to the first top electrode 104(A) is greater than a second distance D2 from the second layer 122B of the second material 126 to the second top electrode 104(B).

Each of the layers 124A and 124B of the second material 126 may be at a same distance or different distances from the bottom electrode 112 in the respective first and second regions 108A and 108B. Since acoustic waves propagate differently through materials of different acoustic impedance, alternating from the first material 120 to the second material 126 in the layers 122A and 122B provides the acoustic mirror 118 that interrupts the propagation of acoustic waves and reflects such acoustic waves to reduce energy loss. This mirror effect is further improved by the additional layers 124A and 124B, which are also disposed opposite to the first and second top electrodes 104A and 104B, respectively, and are spaced from the layers 122A and 122B, respectively, by the first material 120. A distance between layer 122A and layer 124A may be the same or different than a distance between layer 122B and layer 124B. The first material 120 is also provided around the layers 124A and 124B and may be coupled to, bonded to, or provided on a (common) substrate 128 of the BAW device 100.

In some examples, a distance between the bottom electrode 112 and the acoustic mirror 118 in the first region 108A may be the same as a distance between the bottom electrode 112 and the acoustic mirror in the second region 108B. In such examples, the acoustic mirror 118 in the first region 108A is offset (e.g., in a thickness direction or vertical direction) from the acoustic mirror 118 in the second region 108B.

On the optionally planar surface 106 of the piezoelectric layer 110, the BAW device 100 also includes lateral acoustic features 130A and 130B, respectively disposed on the respective region of the optionally planar, surface 106 around perimeter 132A of the first top electrode 104A and perimeter 132B of the second top electrode 104B. In some examples, the lateral acoustic features 130A and 130B are disposed around the entire perimeters 132A and 132B. In other examples, one or both of the lateral acoustic features 130A and 130B may be disposed around only a portion of the perimeters 132A and 132B. The lateral acoustic features 130A and 130B help reduce lateral flow of acoustic waves along the optionally planar surface 106 and direct more of the acoustic energy in a direction through the piezoelectric layer 110 toward the bottom electrode 112. Lateral acoustic waves traveling between the first top electrode 104A and the second top electrode 104B along the, optionally planar, surface 106 can cause interference between the first acoustic resonator 102A and the second acoustic resonator 102B. Thus, the lateral acoustic features 130A and 130B suppress spurious modes in the first acoustic resonator 102A and the second acoustic resonator 102B and also reduce energy loss.

Another factor contributing to the efficiency of the BAW device 100 is the regularity of a crystalline structure of the piezoelectric layer 110. The piezoelectric layer 110 may be epitaxially grown to have a highly regular or uniform crystalline structure. In addition, the piezoelectric layer 110 may have an in-plane orientation with respect to a seed layer (not shown in FIG. 1) on which it has been grown, as discussed further below. As such, the piezoelectric layer 110 can more efficiently convert the electromagnetic field generated between, for example, the first top electrode 104A and the bottom electrode 112 than a piezoelectric layer in which the crystalline structure has less regularity. The regularity of a crystalline structure grown by epitaxy depends, in part, on the surface upon which it is grown. As explained in further detail below, growing the piezoelectric layer 110 on a high-quality, e.g., planar, seed layer allows the crystalline structure to be grown with an in-plane orientation with respect to the seed layer on which it has been grown, which increases the efficiency of BAW device 100.

FIG. 2 is a cross-sectional view of a conventional BAW device 200 that is functionally similar but structurally different from the exemplary BAW device 100 in FIG. 1. The BAW device 200 includes a first acoustic resonator 202A in a first region 204A of a piezoelectric layer 206 and a second acoustic resonator 202B in a second region 204B of the piezoelectric layer 206. The first acoustic resonator 202A includes a first top electrode 208A disposed in a recess 210 on a first side 212 of the piezoelectric layer 206, whereas a second top electrode 208B of the second acoustic resonator 202B is on a surface 214 on the first side 212. In other words, the first side 212 has at least two levels, e.g., with a step between them, as shown in FIG. 2. The BAW device 200 includes a bottom electrode 216 (directly) underneath (i.e., against) a planar surface 218 on a second side 220 of the piezoelectric layer 206. A difference between the resonant frequency of the first acoustic resonator 202A and the second acoustic resonator 202B is due to the recess 210, which causes a thickness T_{P3} of the piezoelectric layer 206 in the first region 204A to be less than a thickness T_{P4} of the piezoelectric layer 206 in the second region 204B.

The bottom electrode 216 is disposed between the planar surface 218 and an acoustic mirror 222, which is formed of a first material 224 having a first acoustic impedance and layers 226A, 226B, 228A, and 228B of a second material 230 having a second acoustic impedance. The acoustic mirror 222 is formed on a substrate 232.

Regularity of a crystalline structure of the piezoelectric layer 206 has a limitation in the degree of orientation in the preferred direction when grown on the bottom electrode 216 and on the first material 224 (e.g., an amorphous layer). Therefore, the Q factor of the conventional BAW device 200 is reduced by the manner in which the piezoelectric layer 206 is formed. In detail, the first material 224 and layers 226A, 226B, 228A, and 228B are formed sequentially on top of the substrate 232. The first material 224, which is a low acoustic impedance material such as amorphous SiO₂, does not provide a highly regular surface from which to grow a crystalline structure. As a result, the crystalline structure of the piezoelectric layer 206 does not grow with an in-plane orientation with respect to the first material 224, on which the crystalline structure is grown. The bottom electrode 216 also does not provide a highly uniform surface compatible with epitaxial growth of the crystalline structure of the piezoelectric layer 206. Despite efforts to address this problem, the regularity of the piezoelectric layer 206 continues to be a problem with conventional BAW devices, such as the BAW device 200.

The BAW device 200 also includes lateral acoustic features 236A and 236B around perimeters 238A and 238B of the first top electrode 208A and the second top electrode 208B, respectively. The lateral acoustic features 236A and 236B may, for instance, be formed by a process involving photolithography prior to formation of the first top electrode 208A and the second top electrode 208B. Due to the reduced thickness T_{P3} of the piezoelectric layer 206 in the first region 204A compared to the thickness T_{P4} in the second region 204B, the lateral acoustic features 236A and 236B are at different focal distances from a lens of a photolithographic apparatus. Consequently, one or more steps for forming the lateral acoustic feature 236A may be repeated to form the lateral acoustic feature 236B, which raises manufacturing cost of the BAW device 200.

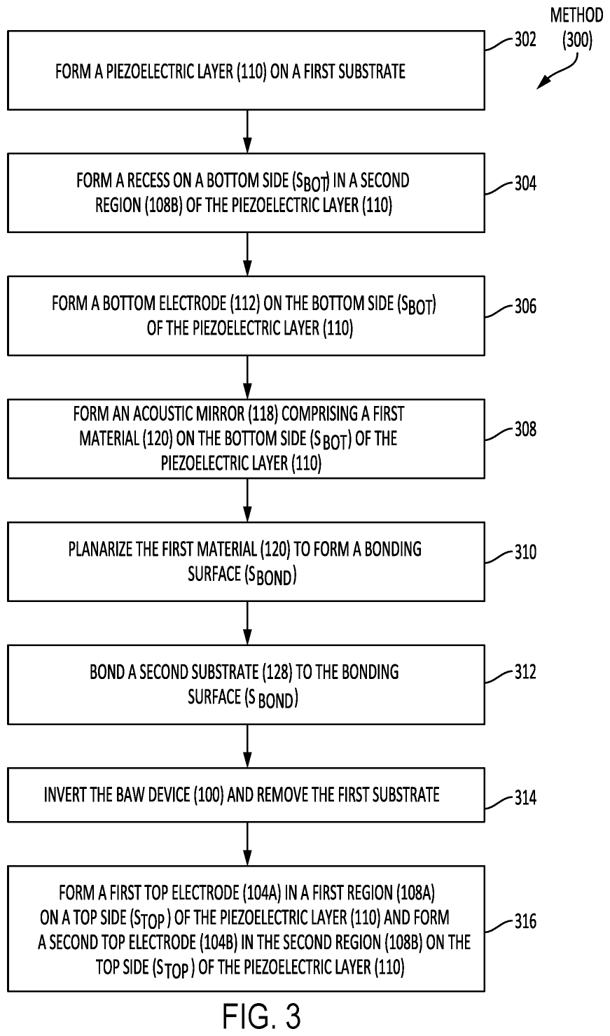

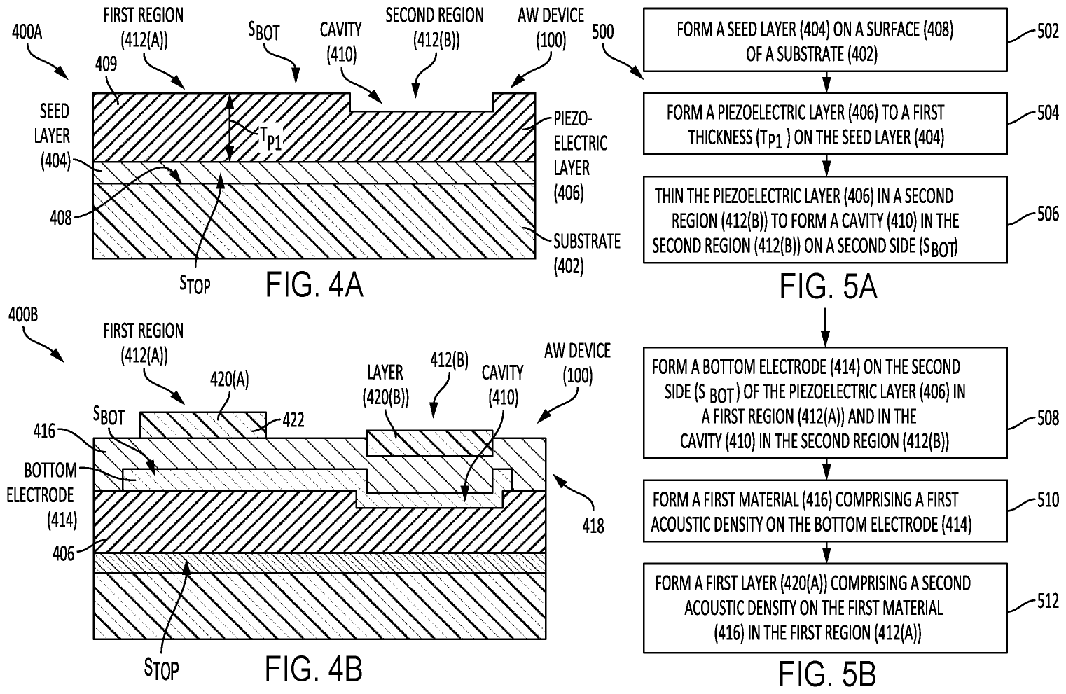

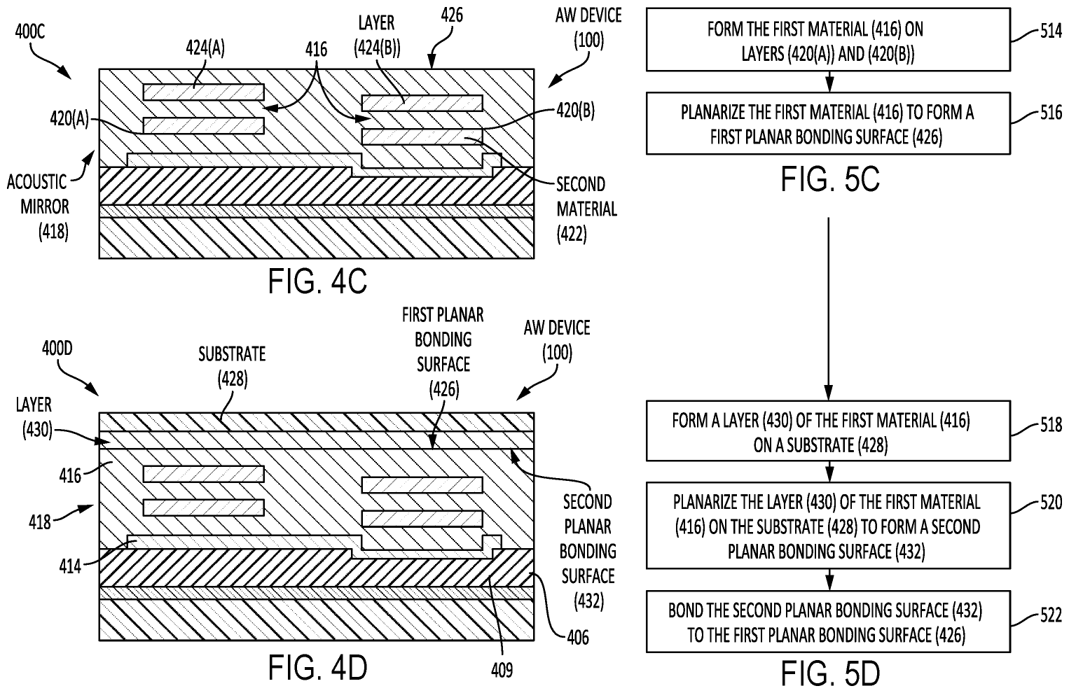

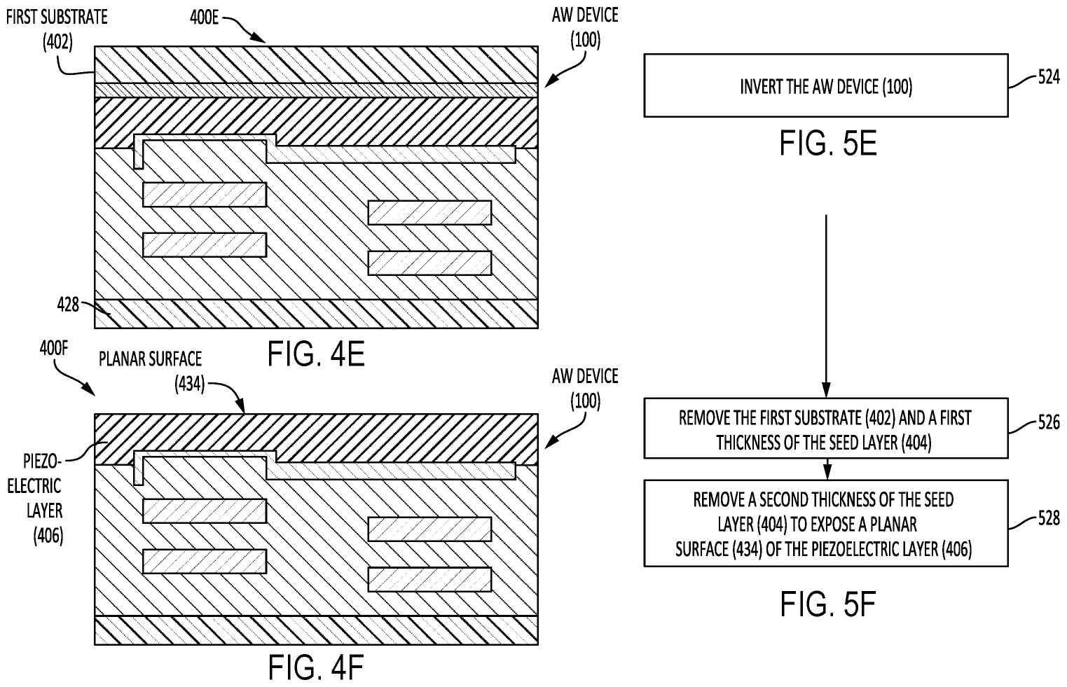

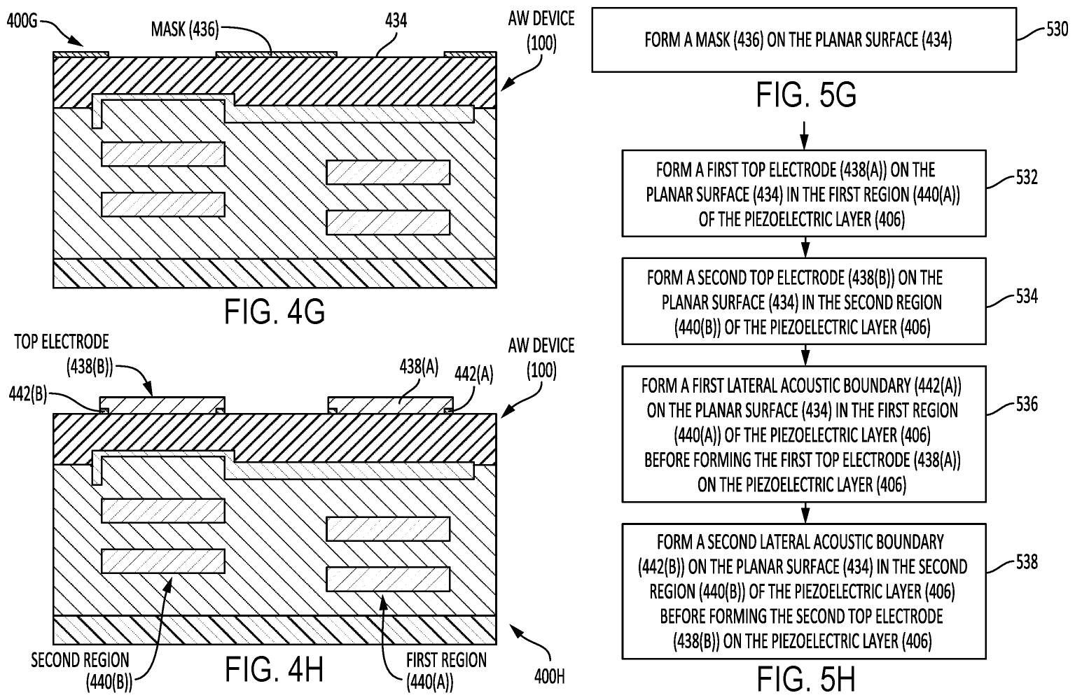

FIG. 3 is a flowchart illustrating an exemplary method 300 for fabricating the BAW device 100 in FIG. 1. The method includes forming a piezoelectric layer 110 on a first substrate (block 302). Details of forming the piezoelectric layer 110 are explained with reference to the fabrication stage 400A in FIG. 4A. The method includes forming a recess on a bottom side S_{BOT} in a second region 108B of the piezoelectric layer 110 (block 304). The method includes forming a bottom electrode 112 on the bottom side S_{BOT} of the piezoelectric layer 110 (block 306). The method further includes forming an acoustic mirror 118 comprising a first material 120 on the bottom side S_{BOT} of the piezoelectric layer 110 (block 308). The method includes planarizing the first material 120 to form a bonding surface S_{BOND} (block 310). The method includes bonding a second substrate 128 to the bonding surface S_{BOND} (block 312). The method includes inverting the BAW device 100 and removing the first substrate (block 314). The method further includes forming a first top electrode 104A in a first region 108A on a top side STOP of the piezoelectric layer 110 and forming a second top electrode 104B in the second region 108B on the top side STOP of the piezoelectric layer 110 (block 316).

The method 300 is explained in more detail with reference to the fabrication stages 400A-400H in FIGS. 4A-4H. The flowchart 500 describes the corresponding fabrication in FIGS. 5A-5H.

FIG. 4A is an illustration of the BAW device 100 (shown in FIG. 1) in a first fabrication stage 400A. In FIG. 4A, the BAW device 100 includes a first substrate 402 (e.g., as a temporary/sacrificial substrate), an optional seed layer 404, and a piezoelectric layer 406. As stated in FIG. 5A, forming the piezoelectric layer 406 may optionally include forming the seed layer 404 on a surface 408 of the first substrate 402 (block 502). The seed layer 404 may provide a surface for forming (e.g., by epitaxial growth) of the piezoelectric layer 406 with a highly uniform crystalline structure. Forming the piezoelectric layer 406 includes forming the piezoelectric layer 406 to a first thickness T_{P1} on the seed layer 404 (block 504) or directly on the first substrate 402. In some examples, the piezoelectric layer 406 may be the piezoelectric layer 110 in FIG. 1. The seed layer 404 may be metallic aluminum (Al) or aluminum nitride (AlN) deposited on the first substrate 402 by sputtering, laser deposition, or metal oxide chemical vapor deposition (MOCVD) for example. The piezoelectric layer 406 may be AlN or aluminum scandium nitride (AlScN), e.g., formed under epitaxial growth conditions and/or up to two (2) microns in thickness.

The piezoelectric layer 406 may include a recess 410 on a second side S_{BOT} opposite the first substrate 402. In this regard, forming the piezoelectric layer 406 also includes thinning the piezoelectric layer 406 in the second region 412B to form a recess 410 in the second region 412B on the second side S_{BOT} (block 506). Thinning the piezoelectric layer 406 to form the recess 410 may include chemical etching, ion beam etching, and ion cluster trimming, for example.

FIG. 4B is an illustration of the BAW device 100 in a second fabrication stage 400B. In FIG. 4B, the BAW device 100 further includes a bottom electrode 414, an acoustic mirror 418, and layers 420A and 420B of a second material 422 of the acoustic mirror 418. The bottom electrode 414, first material 416, and layers 420A and 420B may correspond to the bottom electrode 112, the first material 120, and the layers 122A and 122B, in some examples.

As described in FIG. 5B, forming the bottom electrode 414 may include forming the bottom electrode 414 on the second side S_{BOT} of the piezoelectric layer 406 in the first region 412A and in the recess 410 in the second region 412B (block 508). Forming the bottom electrode 414 may alternatively include forming the bottom electrode 414 on the second side S_{BOT} of the piezoelectric layer 406 in the first region 412A and forming a second bottom electrode (not shown) in the recess 410 on the second side S_{BOT} of the piezoelectric layer 406 in the second region 412B. In such an example, the bottom electrode 414 and the second bottom electrode may be electrically coupled to each other. The bottom electrode 414 may be formed to a thickness of 100 to 300 nanometers in a non-limiting example.

Also described in FIG. 5B, forming the acoustic mirror 418 includes forming the first material 416 comprising a first acoustic impedance on the bottom electrode 414 and on the exposed area of the piezoelectric layer 406 (block 510). Forming the acoustic mirror 418 also includes forming a first layer 420A comprising a second acoustic impedance on the first material 416 in the first region 412A (block 512) and forming a second layer 420B comprising the second acoustic impedance on the first material 416 in the second region 412B. Characteristics of the acoustic mirror 418 may be varied by changing materials and respective thicknesses of the first material 416, the first layer 420A, and the second layer 420B.

FIG. 4C is an illustration of the BAW device 100 in a third fabrication stage 400C. In FIG. 4C, the BAW device 100 further includes layers 424A and 424B of the second material 422 of the acoustic mirror 418 and the first material 416 of the acoustic mirror 418 between the layers 420A and 420B and the layers 424A and 424B.

As described in FIG. 5C, forming the acoustic mirror 418 further includes forming the first material 416 on the layers 420A and 420B (block 514). In some examples, forming the acoustic mirror 418 also includes forming the layers 424A and 424B on the first material 416 and forming additional first material 416 on the layers 424A and 424B. Forming the acoustic mirror 418 may further include planarizing the additional first material 416 to form a first bonding surface 426 (block 516). As described above with reference to FIG. 1, layer 420A may be at a distance D1 from a surface of the seed layer 404 in the first region 412A, and layer 420B may be at a second distance D2 from the surface of the seed layer 404 in the second region 412B, where D1 may be greater than D2. Each of the layers 424A and 424B of the second material 422 may be at a same distance or different distances from the bottom electrode 414 in the respective first and second regions 412A and 412B. Since acoustic waves propagate differently through materials of different acoustic impedance, alternating from the first material 416 to the second material 422 in the layers 420A and 420B provides the acoustic mirror 418 that interrupts the propagation of acoustic waves and reflects such acoustic waves to reduce energy loss. This mirror effect is further improved by the additional layers 424A and 424B, which are also disposed on (e.g., above) the bottom electrode 414 and are spaced from the layers 420A and 420B, respectively, by the first material 416. A distance between layer 420A and layer 424A may be the same or different than a distance between layer 420B and layer 424B. The first material 416 is also provided around the layers 424A and 424B.

FIG. 4D is an illustration of the BAW device 100 in a fourth fabrication stage 400D. In FIG. 4D, the BAW device 100 further includes a substrate 428, which may be silicon (Si), for example, and optionally, a layer 430 of the first material 416. As described in FIG. 5D, forming the BAW device 100 may further include forming the layer 430 of the first material 416 on the substrate 428 (block 518) and planarizing the layer 430 of the first material 416 on the substrate 428 to form a second bonding surface 432 (block 520). Alternatively, a respective surface of the substrate 428 may serve as a second planar bonding surface for direct bonding to the first bonding surface 426 of the acoustic mirror 418. Planarization may be performed on the respective surface of the substrate 428 before bonding. In some examples, the layer 430 may be made of a different material than the first material 416, such as the second material 422. In even further examples, layer 430 may comprise two or more layers. The method further includes bonding the second bonding surface 432 to the first bonding surface 426 (block 522). Here, the bonding may be an SiO₂—SiO₂ bond, requiring deposition and preprocessing of the interface on the substrate 428. However, other bond methods like SiO₂—Si direct bonding, or any other known methods, are applicable as well. The bonding may be included in a layer-to-layer transfer of the piezoelectric layer 406, making it possible to epitaxially grow the piezoelectric layer 406 with the highly uniform crystalline structure on a first substrate before being transferred to a second substrate. In this process, the piezoelectric layer 406, the bottom electrode 414, and the acoustic mirror 418 are grown in reverse order to the method of fabricating the conventional BAW device 200 and thereby reducing irregularities in the piezoelectric layer 406.

FIG. 4E is an illustration of the BAW device 100 in a fifth fabrication stage 400E with the first substrate 402 on top and the substrate 428 at the bottom in this orientation. In other words, the orientation of the layer stack of FIG. 4E has been inverted with respect to FIG. 4D. As described in FIG. 5E, forming the BAW device 100 may include inverting the BAW device 100 (block 524). The substrate 428, to which the BAW device 100 is bonded, becomes the structural support for the BAW device 100. In some examples, inverting the BAW device may be omitted.

FIG. 4F is an illustration of the BAW device 100 in a sixth fabrication stage 400F. As described in FIG. 5F, forming the BAW device 100 further includes removing the first substrate 402. If present, additionally, the seed layer 404 may be removed. In some examples, a first thickness of the seed layer 404 may be removed together with removing the first substrate 402 (block 526). For example, the first substrate 402 and the first thickness of the seed layer 404 may be removed by mechanical grinding or polishing, leaving a second thickness of the seed layer 404 coating the piezoelectric layer 406. Forming the BAW device 100 may further comprise removing the second thickness of the seed layer 404 to expose a planar surface 434 of the piezoelectric layer 406 (block 528). In some examples, removing the second thickness of the seed layer 404 includes selectively etching the seed layer 404 to expose the planar surface 434 of the piezoelectric layer 406 that may have been epitaxially grown on the seed layer 404. The planar surface 434 of the piezoelectric layer 406 may be used directly for the subsequently described manufacturing of the top electrodes. In some examples, however, further processing may be applied to the surface 434 of the piezoelectric layer 406, such as thinning the piezoelectric layer in one or more regions corresponding to the first region 412A and the second region 412B of the bottom electrode 414. The thinning may produce a piecewise planar surface of the piezoelectric layer wherein different thicknesses of the piezoelectric layer may be associated with the corresponding regions of the piezoelectric layer, similar to the above-described formation of the bottom electrode 414. The thinning on the top side STOP of the piezoelectric layer 406 may be performed in addition or instead of the thinning on the bottom side S_{BOT} of the piezoelectric layer as described above.

FIG. 4G is an illustration of the BAW device 100 in a seventh fabrication stage 400G in which a mask 436 is disposed on the, optionally planar, surface 434 for formation of a first top electrode 438A and a second top electrode 438B (see FIG. 4H). As mentioned above, at least one of the first and the second top electrodes may be formed in a thinned region of the surface 434. As described in FIG. 5G, forming the first top electrode 438A further comprises forming the mask 436 on the, optionally planar, surface 434 (block 530). The mask 436 may be a photoresist material formed by any process known in the art.

FIG. 4H is an illustration of the BAW device 100 in an eighth fabrication stage 400H. As described in FIG. 5H, forming the first top electrode 438A and the second top electrode 438B includes forming the first top electrode 438A on the, optionally planar, surface 434 in a first region 440A of the piezoelectric layer 406 (block 532) and forming the second top electrode 438B on the, optionally planar, surface 434 in a second region 440B of the piezoelectric layer 406 (block 534).

Forming the first top electrode 438A and the second top electrode 438B may further comprise forming a first lateral acoustic feature 442A on the, optionally planar, surface 434 in the first region 440A of the piezoelectric layer 406 before forming the first top electrode 438A on the piezoelectric layer 406 (block 536) and forming a second lateral acoustic feature 442B on the, optionally planar, surface 434 in the second region 440B of the piezoelectric layer 406 before forming the second top electrode 438B on the piezoelectric layer 406 (block 538). Forming the first lateral acoustic feature 442A and the second lateral acoustic feature 442B may further include, for example, at least depositing an additional mask, depositing the first lateral acoustic feature 442A and the second lateral acoustic feature 442B, and removing the additional mask before forming the mask 436.

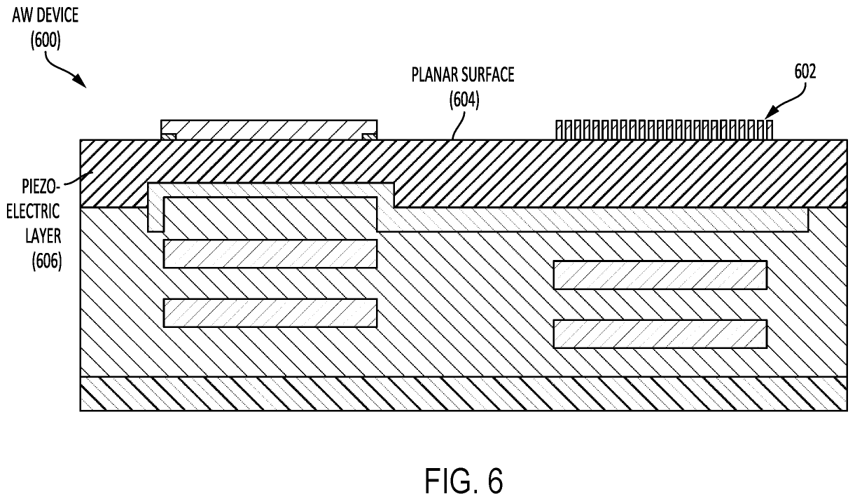

FIG. 6 is an illustration of another BAW device 600 that may correspond, except as described herein, to the BAW device 100 in FIG. 1. As an alternative to the first top electrode 104A in the first region 108A to form a BAW resonator, BAR SMR, or BAR (T)FBAR, the BAW device 600 includes an electrode 602 on an, optionally planar, surface 604 of the piezoelectric layer 606. The electrode 602 may be an interdigitated transducer (IDT) electrode. The BAW device 600 may alternatively or additionally include a Lame-mode bulk resonator or a Lamb wave resonator.

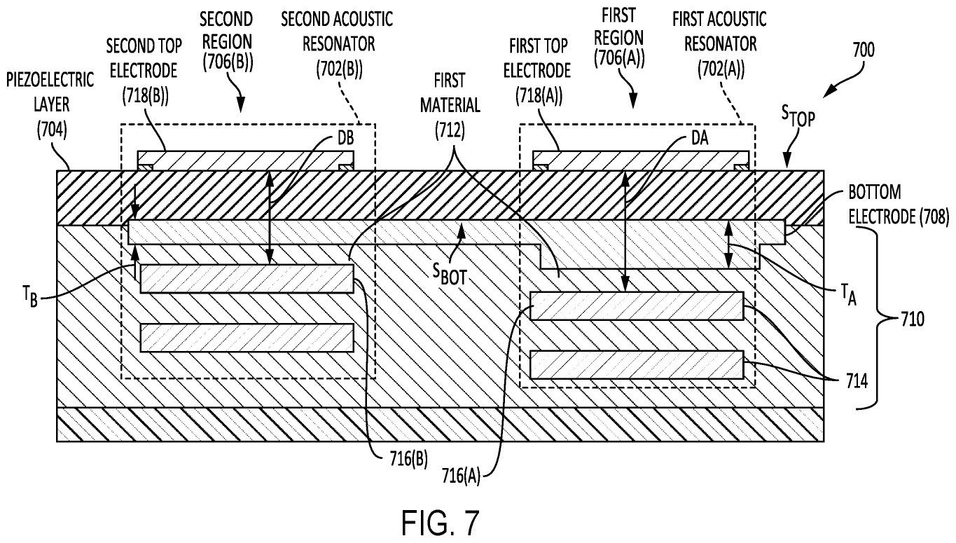

FIG. 7 is an illustration of yet another BAW device 700 in which a crystalline structure of a piezoelectric layer 704 has an in-plane orientation with respect to a seed layer (already removed in FIG. 7) on which it was grown, which increases acoustic efficiency of the BAW device 700. As in the BAW device 200 in FIG. 2, the BAW device 700 includes a first acoustic resonator 702(A) and a second acoustic resonator 702(B) with different resonant frequencies. However, unlike the BAW device 200 in FIG. 2, the BAW device 700 does not include a recess of the piezoelectric layer 704 to create a different resonant frequency. After the piezoelectric layer 704 of the BAW device 700 is epitaxially grown on a seed layer having a high regularity, like the seed layer 404 in FIG. 4A, the piezoelectric layer 704 is not thinned in one area. Instead, a bottom electrode 708 is formed on the piezoelectric layer 704 with a greater thickness TA in the first acoustic resonator 702(A) and a thickness TB in the second acoustic resonator 702(B). The BAW device 700 further includes an acoustic mirror 710 on the bottom side S_{BOT} of the piezoelectric layer 704, and the bottom electrode 708 is between the acoustic mirror 710 and the piezoelectric layer 704. The first thickness TA of the bottom electrode 708 in the first region 706(A) of the piezoelectric layer 704 is different (e.g., thicker) than the second thickness TB of the piezoelectric layer 704 in the second region 706(B).

In an example, the bottom electrode 708 may be initially formed as a layer of uniform thickness TB, and a second layer is formed for a total thickness TA only in the first acoustic resonator 702(A). Alternatively, the bottom electrode 708 may be initially formed as a layer of uniform thickness TA, and the bottom electrode 708 is thinned in the first region 706(A) to the thickness TB. The greater thickness TA of the bottom electrode 708 causes a resonant frequency of the first acoustic resonator 702(A) to be lower than a resonant frequency of the second acoustic resonator 702(B). The BAW device 700 is otherwise fabricated in the manner described above with regard to FIGS. 4A-4H. In some examples, manufacturing a bottom electrode 708 with different thicknesses in the first and second acoustic resonators may be combined with the above-described thinning of the piezoelectric layer 704 in at least one of the first and second acoustic resonators on the bottom side S_{BOT} and/or the top side STOP of the piezoelectric layer 704.

The acoustic mirror 710 includes a first material 712 disposed on the bottom electrode 708. The acoustic mirror 710 also includes a second material 714 disposed in a first layer 716(A) on the first material 712 in the first region. The second material 714 is also disposed in a second layer 716(B) on the first material 712 in the second region 706(B). A first distance DA from the first layer 716(A) of the second material 714 to the first top electrode 718(A) is greater than a second distance DB from the second layer 716(B) of the second material 714 to the second top electrode 718(B), due to the difference between thickness TA and thickness TB.

According to aspects disclosed herein, the acoustic wave device with tuned resonator piezoelectric thickness may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multi copter.

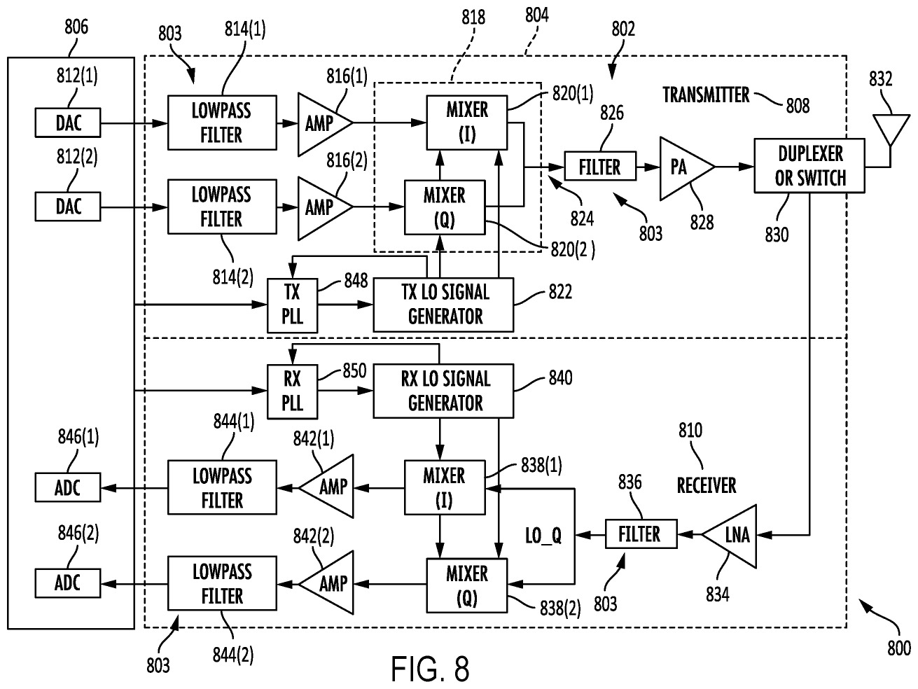

FIG. 8 illustrates an exemplary wireless communications device 800 that includes radio-frequency (RF) components formed from one or more integrated circuits (ICs) 802 and can include an exemplary BAW device manufactured according to any of the aspects described herein, e.g., in which top electrodes are disposed on an, optionally planar, surface of a piezoelectric layer that is thinned in a region to tune acoustic resonators to different frequencies, as illustrated in FIGS. 1 and 4A-4H, and according to any of the aspects disclosed herein. The wireless communications device 800 may include or be provided in any of the above-referenced devices as examples. As shown in FIG. 8, the wireless communications device 800 includes a transceiver 804 and a data processor 806. The data processor 806 may include a memory to store data and program codes. The transceiver 804 includes a transmitter 808 and a receiver 810 that support bi-directional communications. In general, the wireless communications device 800 may include any number of transmitters 808 and/or receivers 810 for any number of communication systems and frequency bands. All or a portion of the transceiver 804 may be implemented on one or more analog ICs, RFICs, mixed-signal ICs, etc.

The transmitter 808 or the receiver 810 may be implemented with a super-heterodyne architecture or a direct-conversion architecture. In the super-heterodyne architecture, a signal is frequency-converted between RF and baseband in multiple stages, e.g., from RF to an intermediate frequency (IF) in one stage and then from IF to baseband in another stage. In the direct-conversion architecture, a signal is frequency-converted between RF and baseband in one stage. The super-heterodyne and direct-conversion architectures may use different circuit blocks and/or have different requirements. In the wireless communications device 800 in FIG. 8, the transmitter 808 and the receiver 810 are implemented with the direct-conversion architecture.

In the transmit path, the data processor 806 processes data to be transmitted and provides I and Q analog output signals to the transmitter 808. In the exemplary wireless communications device 800, the data processor 806 includes digital-to-analog converters (DACs) 812(1), 812(2) for converting digital signals generated by the data processor 806 into the I and Q analog output signals, e.g., I and Q output currents, for further processing.

Within the transmitter 808, lowpass filters 814(1), 814(2) filter the I and Q analog output signals, respectively, to remove undesired signals caused by the prior digital-to-analog conversion. The lowpass filters 814(1), 814(2) may be implemented as BAW filter packages 803. Amplifiers (AMPs) 816(1), 816(2) amplify the signals from the lowpass filters 814(1), 814(2), respectively, and provide I and Q baseband signals. An upconverter 818 upconverts the I and Q baseband signals with I and Q transmit (TX) local oscillator (LO) signals from a TX LO signal generator 822 through mixers 820(1), 820(2) to provide an upconverted signal 824. A filter 826 filters the upconverted signal 824 to remove undesired signals caused by the frequency upconversion as well as noise in a receive frequency band. A power amplifier (PA) 828 amplifies the upconverted signal 824 from the filter 826 to obtain the desired output power level and provides a transmit RF signal. The transmit RF signal is routed through a duplexer or switch 830 and transmitted via an antenna 832. Any of the lowpass filters 814(1) and 814(2), or the filter 826, may be an acoustic wave filter (AW filter) packages 803.

In the receive path, the antenna 832 receives signals transmitted by base stations and provides a received RF signal, which is routed through the duplexer or switch 830 and provided to a low noise amplifier (LNA) 834. The duplexer or switch 830 is designed to operate with a specific receive (RX)-to-TX duplexer frequency separation, such that RX signals are isolated from TX signals. The received RF signal is amplified by the LNA 834 and filtered by a filter 836 to obtain a desired RF input signal. Downconversion mixers 838(1), 838(2) mix the output of the filter 836 with I and Q RX LO signals (i.e., LO_I and LO_Q) from an RX LO signal generator 840 to generate I and Q baseband signals. The I and Q baseband signals are amplified by AMPs 842(1), 842(2) and further filtered by lowpass filters 844(1), 844(2) to obtain I and Q analog input signals, which are provided to the data processor 806. Any of the filter 836 and the lowpass filters 844(1), 844(2) may be BAW filter packages 803. In this example, the data processor 806 includes analog-to-digital converters (ADCs) 846(1), 846(2) for converting the analog input signals into digital signals to be further processed by the data processor 806.

In the wireless communications device 800 of FIG. 8, the TX LO signal generator 822 generates the I and Q TX LO signals used for frequency upconversion, while the RX LO signal generator 840 generates the I and Q RX LO signals used for frequency downconversion. Each LO signal is a periodic signal with a particular fundamental frequency. A TX phase-locked loop (PLL) circuit 848 receives timing information from the data processor 806 and generates a control signal used to adjust the frequency and/or phase of the TX LO signals from the TX LO signal generator 822. Similarly, an RX PLL circuit 850 receives timing information from the data processor 806 and generates a control signal used to adjust the frequency and/or phase of the RX LO signals from the RX LO signal generator 840.

Wireless communications devices 800 that can each include an exemplary BAW device manufactured according to any of the aspects described herein, e.g., in which top electrodes are disposed on an, optionally planar, surface of a piezoelectric layer that is thinned in a region to tune acoustic resonators to different frequencies, as illustrated in FIGS. 1 and 4A-4H, and according to any of the aspects disclosed herein, may be provided in or integrated into any processor-based device. Examples, without limitation, include a set-top box, an entertainment unit, a navigation device, a communications device, a fixed location data unit, a mobile location data unit, a global positioning system (GPS) device, a mobile phone, a cellular phone, a smartphone, a session initiation protocol (SIP) phone, a tablet, a phablet, a server, a computer, a portable computer, a mobile computing device, a wearable computing device (e.g., a smartwatch, a health or fitness tracker, eyewear, etc.), a desktop computer, a personal digital assistant (PDA), a monitor, a computer monitor, a television, a tuner, a radio, a satellite radio, a music player, a digital music player, a portable music player, a digital video player, a video player, a digital video disc (DVD) player, a portable digital video player, an automobile, a vehicle component, avionics systems, a drone, and a multicopter.

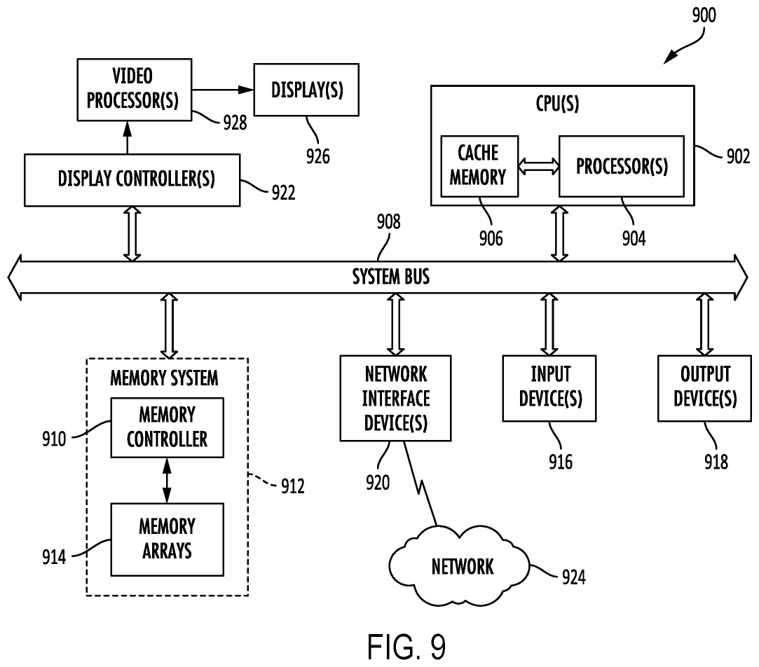

FIG. 9 illustrates an example of a processor-based system 900 including circuits including an exemplary BAW device manufactured according to any of the aspects described herein, e.g., in which top electrodes are disposed on an, optionally planar, surface of a piezoelectric layer that is thinned in a region to tune acoustic resonators to different frequencies, as illustrated in FIGS. 1 and 4A-4H, and according to any aspects disclosed herein. In this example, the processor-based system 900 includes one or more central processor units (CPUs) 902, which may also be referred to as CPU or processor cores, each including one or more processors 904. The CPU(s) 902 may have cache memory 906 coupled to the processor(s) 904 for rapid access to temporarily stored data. The CPU(s) 902 is coupled to a system bus 908 and can intercouple master and slave devices included in the processor-based system 900. As is well known, the CPU(s) 902 communicates with these other devices by exchanging address, control, and data information over the system bus 908. For example, the CPU(s) 902 can communicate bus transaction requests to a memory controller 910 as an example of a slave device. Although not illustrated in FIG. 9, multiple system buses 908 could be provided; wherein each system bus 908 constitutes a different fabric.

Other master and slave devices can be connected to the system bus 908. As illustrated in FIG. 9, these devices can include a memory system 912 that includes the memory controller 910 and one or more memory arrays 914, one or more input devices 916, one or more output devices 918, one or more network interface devices 920, and one or more display controllers 922, as examples. The input device(s) 916 can include any type of input device, including, but not limited to, input keys, switches, voice processors, etc. The output device(s) 918 can include any type of output device, including, but not limited to, audio, video, other visual indicators, etc. The network interface device(s) 920 can be any device configured to allow an exchange of data to and from a network 924. The network 924 can be any type of network, including, but not limited to, a wired or wireless network, a private or public network, a local area network (LAN), a wireless local area network (WLAN), a wide area network (WAN), a BLUETOOTH™ network, and the Internet. The network interface device(s) 920 can be configured to support any type of communications protocol desired.

The CPU(s) 902 may also be configured to access the display controller(s) 922 over the system bus 908 to control information sent to one or more displays 926. The display controller(s) 922 sends information to the display(s) 926 to be displayed via one or more video processors 928, which process the information to be displayed into a format suitable for the display(s) 926. The display(s) 926 can include any type of display, including, but not limited to, a cathode ray tube (CRT), a liquid crystal display (LCD), a plasma display, or a light-emitting diode (LED) display, etc.

Those of skill in the art will further appreciate that the various illustrative logical blocks, modules, circuits, and algorithms described in connection with the aspects disclosed herein may be implemented as electronic hardware, instructions stored in memory or another computer-readable medium and executed by a processor or other processing device, or combinations of both. The master and slave devices described herein may be employed in any circuit, hardware component, IC, or IC chip, as examples. Memory disclosed herein may be any type and size of memory and may be configured to store any type of information desired. To clearly illustrate this interchangeability, various illustrative components, blocks, modules, circuits, and steps have been described above generally in terms of their functionality. How such functionality is implemented depends upon the particular application, design choices, and/or design constraints imposed on the overall system. Skilled artisans may implement the described functionality in varying ways for each particular application, but such implementation decisions should not be interpreted as causing a departure from the scope of the present disclosure.

The various illustrative logical blocks, modules, and circuits described in connection with the aspects disclosed herein may be implemented or performed with a processor, a Digital Signal Processor (DSP), an Application Specific Integrated Circuit (ASIC), a Field Programmable Gate Array (FPGA) or other programmable logic device, discrete gate or transistor logic, discrete hardware components, or any combination thereof designed to perform the functions described herein. A processor may be a microprocessor, but in the alternative, the processor may be any conventional processor, controller, microcontroller, or state machine. A processor may also be implemented as a combination of computing devices (e.g., a combination of a DSP and a microprocessor, a plurality of microprocessors, one or more microprocessors in conjunction with a DSP core, or any other such configuration).

The aspects disclosed herein may be embodied in hardware and in instructions that are stored in hardware and may reside, for example, in Random Access Memory (RAM), flash memory, Read-Only Memory (ROM), Electrically Programmable ROM (EPROM), Electrically Erasable Programmable ROM (EEPROM), registers, a hard disk, a removable disk, a CD-ROM, or any other form of computer-readable medium known in the art. An exemplary storage medium is coupled to the processor such that the processor can read information from and write information to the storage medium. In the alternative, the storage medium may be integral to the processor. The processor and the storage medium may reside in an ASIC. The ASIC may reside in a remote station. Alternatively, the processor and the storage medium may reside as discrete components in a remote station, base station, or server.

It is also noted that the operational steps described in any of the exemplary aspects herein are described to provide examples and discussion. The operations described may be performed in numerous different sequences other than the illustrated sequences. Furthermore, operations described in a single operational step may actually be performed in several different steps. Additionally, one or more operational steps discussed in the exemplary aspects may be combined. It is to be understood that the operational steps illustrated in the flowchart diagrams may be subject to numerous different modifications as will be readily apparent to one of skill in the art. Those of skill in the art will also understand that information and signals may be represented using various technologies and techniques. For example, data, instructions, commands, information, signals, bits, symbols, and chips that may be referenced throughout the above description may be represented by voltages, currents, electromagnetic waves, magnetic fields or particles, optical fields or particles, or any combination thereof.

The previous description of the disclosure is provided to enable any person skilled in the art to make or use the disclosure. Various modifications to the disclosure will be readily apparent to those skilled in the art, and the generic principles defined herein may be applied to other variations. Thus, the disclosure is not intended to be limited to the examples and designs described herein but is to be accorded the widest scope consistent with the principles and novel features disclosed herein.

Implementation examples are described in the following numbered clauses:

1. A bulk acoustic wave (BAW) device comprising:
a piezoelectric layer;
a first top electrode on a top side of the piezoelectric layer in a first region of the piezoelectric layer;
a second top electrode on the top side of the piezoelectric layer in a second region of the piezoelectric layer;
an acoustic mirror on a bottom side of the piezoelectric layer; and
a bottom electrode between the acoustic mirror and the piezoelectric layer,
wherein the piezoelectric layer comprises a recess on the bottom side in the second region of the piezoelectric layer.

2. The BAW device of clause 1, wherein the bottom electrode is disposed in the recess on the bottom side of the piezoelectric layer.

3. The BAW device of clause 1, wherein the bottom electrode comprises:
a first bottom electrode disposed in the recess in the second region of the piezoelectric layer; and
a second bottom electrode disposed in the first region of the piezoelectric layer.

4. The BAW device of any of clause 1 to clause 3, wherein a surface on the top side of the piezoelectric layer is planar.

5. The BAW device of any of clause 1 to clause 4, wherein the acoustic mirror comprises a first material disposed in the recess.

6. The BAW device of any of clause 1 to clause 5, wherein the acoustic mirror comprises:
a first material disposed on the bottom electrode;
a first layer of a second material disposed on the first material at a first distance from the top side of the piezoelectric layer in the first region; and
a second layer of the second material disposed on the first material at a second distance from the top side of the piezoelectric layer in the second region.

7. The BAW device of clause 6, wherein:
the first distance is greater than the second distance.

8. The BAW device of any of clause 1 to clause 7, further comprising:
a substrate coupled to the acoustic mirror.

9. The BAW device of clause 8, further comprising a bonding interface between the acoustic mirror and the substrate.

10. The BAW device of any of clause 1 to clause 9, further comprising:
a first lateral acoustic feature disposed around a perimeter of the first top electrode; and
a second lateral acoustic feature disposed around a perimeter of the second top electrode.

11. The BAW device of any of clause 1 to clause 10 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

12. A method of making a bulk acoustic wave (BAW) device, the method comprising:
forming a piezoelectric layer on a first substrate;
forming a recess in a second region of the piezoelectric layer;
forming a bottom electrode on the piezoelectric layer;
forming an acoustic mirror comprising a first material on the bottom electrode;
planarizing the first material to form a bonding surface;
bonding a second substrate to the bonding surface;
removing the first substrate; and
forming a first top electrode in a first region of the piezoelectric layer and forming a second top electrode in the second region of the piezoelectric layer.

13. The method of clause 12, wherein forming the piezoelectric layer comprises growing the piezoelectric layer on a seed layer.

14. The method of clause 13, wherein the seed layer comprises at least one of metallic aluminum (Al) and aluminum nitride (AlN).

15. The method of any of clause 12 to clause 14 wherein:
the piezoelectric layer comprises a first thickness in the first region; and
forming the recess comprises thinning the piezoelectric layer to a second thickness in the second region.

16. The method of any of clause 12 to clause 15, wherein forming the bottom electrode comprises forming the bottom electrode on the piezoelectric layer in the first region and in the recess in the second region.

17. The method of any of clause 12 to clause 15, wherein forming the bottom electrode comprises forming a first bottom electrode on the piezoelectric layer in the first region and forming a second bottom electrode in the recess in the second region.

18. The method of any of clause 12 to clause 17, wherein forming the acoustic mirror comprises:
forming the first material on the bottom electrode;
forming a first layer of a second material on the first material in the first region;
forming a second layer of the second material on the first material in the second region; and
forming the first material on the first layer and the second layer.

19. The method of any of clause 12 to clause 18, wherein forming the first top electrode and the second top electrode comprises:
forming a first lateral acoustic feature in the first region of the piezoelectric layer before forming the first top electrode; and
forming a second lateral acoustic feature in the second region of the piezoelectric layer before forming the second top electrode.

20. A bulk acoustic wave (BAW) device comprising:
a piezoelectric layer;
a first top electrode on a top side of the piezoelectric layer in a first region of the piezoelectric layer;
a second top electrode on the top side of the piezoelectric layer in a second region of the piezoelectric layer;
an acoustic mirror on a bottom side of the piezoelectric layer; and
a bottom electrode between the acoustic mirror and the piezoelectric layer, the bottom electrode having a first thickness in the first region of the piezoelectric layer and a second thickness different than the first thickness in the second region of the piezoelectric layer.

21. The BAW device of clause 20, wherein the acoustic mirror comprises:
a first material disposed on the bottom electrode;
a first layer of a second material disposed on the first material in the first region; and
a second layer of the second material disposed on the first material in the second region,
wherein a first distance from the first layer of the second material to the first top electrode is greater than a second distance from the second layer of the second material to the second top electrode.

What is claimed is:

1. A bulk acoustic wave (BAW) device comprising:
a piezoelectric layer;
a first top electrode on a top side of the piezoelectric layer in a first region of the piezoelectric layer;
a second top electrode on the top side of the piezoelectric layer in a second region of the piezoelectric layer;
an acoustic mirror on a bottom side of the piezoelectric layer; and
a bottom electrode between the acoustic mirror and the piezoelectric layer,
wherein the piezoelectric layer comprises a recess on the bottom side in the second region of the piezoelectric layer.

2. The BAW device of claim 1, wherein the bottom electrode is disposed in the recess on the bottom side of the piezoelectric layer.

3. The BAW device of claim 1, wherein the bottom electrode comprises:
a first bottom electrode disposed in the recess in the second region of the piezoelectric layer; and
a second bottom electrode disposed in the first region of the piezoelectric layer.

4. The BAW device of claim 1, wherein a surface on the top side of the piezoelectric layer is planar.

5. The BAW device of claim 1, wherein the acoustic mirror comprises a first material disposed in the recess.

6. The BAW device of claim 1, wherein the acoustic mirror comprises:
a first material disposed on the bottom electrode;
a first layer of a second material disposed on the first material at a first distance from the top side of the piezoelectric layer in the first region; and
a second layer of the second material disposed on the first material at a second distance from the top side of the piezoelectric layer in the second region.

7. The BAW device of claim 6, wherein:
the first distance is greater than the second distance.

8. The BAW device of claim 1, further comprising:
a substrate coupled to the acoustic mirror.

9. The BAW device of claim 8, further comprising a bonding interface between the acoustic mirror and the substrate.

10. The BAW device of claim 1, further comprising:
a first lateral acoustic feature disposed around a perimeter of the first top electrode; and
a second lateral acoustic feature disposed around a perimeter of the second top electrode.

11. The BAW device of claim 1 integrated into a device selected from the group consisting of: a set-top box; an entertainment unit; a navigation device; a communications device; a fixed location data unit; a mobile location data unit; a global positioning system (GPS) device; a mobile phone; a cellular phone; a smartphone; a session initiation protocol (SIP) phone; a tablet; a phablet; a server; a computer; a portable computer; a mobile computing device; a wearable computing device; a desktop computer; a personal digital assistant (PDA); a monitor; a computer monitor; a television; a tuner; a radio; a satellite radio; a music player; a digital music player; a portable music player; a digital video player; a video player; a digital video disc (DVD) player; a portable digital video player; an automobile; a vehicle component; avionics systems; a drone; and a multicopter.

12. A method of making a bulk acoustic wave (BAW) device, the method comprising:
forming a piezoelectric layer on a first substrate;
forming a recess in a second region of the piezoelectric layer;
forming a bottom electrode on the piezoelectric layer;
forming an acoustic mirror comprising a first material on the bottom electrode;
planarizing the first material to form a bonding surface;
bonding a second substrate to the bonding surface;
removing the first substrate; and
forming a first top electrode in a first region of the piezoelectric layer and forming a second top electrode in the second region of the piezoelectric layer.

13. The method of claim 12, wherein forming the piezoelectric layer comprises growing the piezoelectric layer on a seed layer.

14. The method of claim 13, wherein the seed layer comprises at least one of metallic aluminum (Al) and aluminum nitride (AlN).

15. The method of claim 12, wherein:
the piezoelectric layer comprises a first thickness in the first region; and
forming the recess comprises thinning the piezoelectric layer to a second thickness in the second region.

16. The method of claim 12, wherein forming the bottom electrode comprises forming the bottom electrode on the piezoelectric layer in the first region and in the recess in the second region.

17. The method of claim 12, wherein forming the bottom electrode comprises forming a first bottom electrode on the piezoelectric layer in the first region and forming a second bottom electrode in the recess in the second region.

18. The method of claim 12, wherein forming the acoustic mirror comprises:
forming the first material on the bottom electrode;
forming a first layer of a second material on the first material in the first region;
forming a second layer of the second material on the first material in the second region; and
forming the first material on the first layer and the second layer.

19. The method of claim 12, wherein forming the first top electrode and the second top electrode comprises:
forming a first lateral acoustic feature in the first region of the piezoelectric layer before forming the first top electrode; and
forming a second lateral acoustic feature in the second region of the piezoelectric layer before forming the second top electrode.

20. A bulk acoustic wave (BAW) device comprising:
a piezoelectric layer;
a first top electrode on a top side of the piezoelectric layer in a first region of the piezoelectric layer;
a second top electrode on the top side of the piezoelectric layer in a second region of the piezoelectric layer;
an acoustic mirror on a bottom side of the piezoelectric layer; and
a bottom electrode between the acoustic mirror and the piezoelectric layer, the bottom electrode having a first thickness in the first region of the piezoelectric layer and a second thickness different than the first thickness in the second region of the piezoelectric layer.

21. The BAW device of claim 20, wherein the acoustic mirror comprises:
a first material disposed on the bottom electrode;
a first layer of a second material disposed on the first material in the first region; and
a second layer of the second material disposed on the first material in the second region,
wherein a first distance from the first layer of the second material to the first top electrode is greater than a second distance from the second layer of the second material to the second top electrode.
